(19) United States
(12) Patent Application Publication
(10) Pub. No.: US 2014/0008679 A1
(43) Pub. Date: Jan. 9, 2014

(54) SUBSTRATE FOR MOUNTING ELEMENT AND OPTICAL MODULE

(71) Applicant: SANYO ELECTRIC CO., LTD., (US)

(72) Inventors: Koutaro DEGUCHI, Moriguchi-shi (JP); Masayuki NAGAMATSU, Moriguchi-shi (JP); Mayumi NAKASATO, Moriguchi-shi (JP)

(73) Assignee: SANYO ELECTRIC CO., LTD., Osaka (JP)

(21) Appl. No.: 13/781,611

(22) Filed: Feb. 28, 2013

Related U.S. Application Data
(63) Continuation of application No. PCT/JP2011/004894, filed on Aug. 31, 2011.

(30) Foreign Application Priority Data
Aug. 31, 2010 (JP) 2010-194829

(51) Int. Cl. H01L 31/0203; H01L 33/48

(52) U.S. Cl. CPC H01L 31/0203; H01L 33/48
USPC 257/98; 257/432; 428/131

(57) ABSTRACT

An opening is provided corresponding to an installation area of a semiconductor element in an insulating resin layer for a base material. A first insulating resin layer is provided on a part of one main surface of the insulating resin layer outside the opening to surround the opening. In addition, a second insulating resin layer coats in a continuous manner: the edge portion of the opening on the one main surface of the insulating resin layer; the end face of the opening passing through the insulating resin layer; and the edge portion of the opening on the other main surface of the insulating resin layer. The upper end portion of the end face of the second insulating resin layer in contact with the one main surface of the insulating resin layer protrudes toward the first insulating resin layer.

### TECHNICAL FIELD

The present invention relates to a substrate for mounting elements used in an optical module such as a camera module and to the optical module using the substrate.

### BACKGROUND TECHNOLOGY

Portable electronic devices such as a mobile phone, a PDA, a DVC, and a DSC are increasingly becoming highly functional by, for example, the addition of a camera function that enables photographing of a person and a landscape. For these products to be accepted in the market, however, it is absolutely necessary for the products to be reduced in size and weight. To achieve the reduction in size and weight, a highly integrated system LSI is desired.

On the other hand, these electronic devices are expected to be more user-friendly and convenient, and thus the LSIs used in the devices are required to have higher functionality and performance. Consequently, while the high integration of an

LSI chip leads to the increase in the number of I/Os, a package itself is strongly requested to have reduced size and thickness as well. In order to achieve such requirement and request at the same time, it is strongly requested to develop a semiconductor package adapted to mount semiconductor components on a substrate with a high density. In order to respond to such request, a semiconductor module, on which the semiconductor components are mounted, is desired to have further reduced thickness.

A camera module as one example of conventional portable electronic devices will be described.

FIG. 9 is a cross-sectional view showing the structure of a conventional camera module. As shown in FIG. 9, the conventional camera module is known to have the structure in which: an optical element chip 5 is attached to a bottom surface side of a base material 9 having an opening 2 in the center part; and a transparent member 6 is installed on a top surface side of the base material 9, on which a lens barrel is mounted, facing the optical element chip 5 across the opening 2. The transparent member 6 is fixed to the edge portion of the opening 2 on the top surface of the base material 9 by an adhesive 15.

### RELATED ART DOCUMENTS

### Patent Documents

### [Patent Document 1] JP 2005-134869 A

### DISCLOSURE OF THE INVENTION

### Problem to be Solved by the Invention

In the conventional camera module, an adhesive sometimes flows into an opening before it is solidified when fixing a transparent member to a base material using the adhesive. On such an occasion, there has been a possibility of decrease in the light-receiving efficiency or light-emitting efficiency of an optical module, since the aperture shape of the opening becomes narrower than the designed shape due to the adhesive flowing into the opening of the base material.

An object of the present invention, in consideration of these problems, is to provide a technology capable of suppressing the inflow of the adhesive to the opening provided in the substrate for mounting elements in the optical module including the substrate for mounting elements, the adhesive being provided for fixing the transparent member to the substrate for mounting elements.

Means to Solve the Problem

One aspect of the present invention is a substrate for mounting elements. The substrate for mounting elements includes: a base material provided with an opening passing therethrough from one main surface to the other main surface; a first insulating resin layer provided at a part of the one main surface of the base material on the outer side of the opening so as to surround the opening; and a second insulating resin layer coating an edge portion of the opening and an end face of the opening continuously on the one main surface of the base material, the edge portion of the opening being separated from an end face of the first insulating resin layer surrounding the opening. The substrate for mounting elements is characterized in that an upper end portion of an end face of the second insulating resin layer in contact with the one main surface of the base material protrudes toward the first insulating resin layer.

According to the substrate for mounting elements of this aspect, the pushed-out adhesive can flow into a gap between the end face of the second insulating resin layer and the one main surface of the base material by pressing down the transparent member, when mounting the transparent member to cover the opening. The more adhesive flows into the gap, the less adhesive used for fixing the transparent member passes between the second insulating resin layer and the transparent member to flow toward the opening.

In the substrate for mounting elements of the above aspect, an angle formed by the one main surface of the base material, which is between the first insulating resin layer and the second insulating resin layer, and the end face of the second insulating resin layer in contact with the edge portion of the opening may be smaller than an angle formed by the one main surface of the base material, which is between the first insulating resin layer and the second insulating resin layer, and the end face of the first insulating resin layer surrounding the opening. A light-shielding property of the second insulating resin layer may be superior to a light-shielding property of the first insulating resin layer. In this case, the second insulating resin layer may contain insulating resin and black powder.

Another aspect of the present invention is an optical module. The optical module is characterized by including: the substrate for mounting elements of any of the aforementioned aspects; an optical lens provided on the one main surface side of the substrate for mounting elements; a transparent member disposed on the one main surface side of the substrate for mounting elements to be superimposed on the second insulating resin layer and cover the opening; an adhesive provided on the one main surface of the base material between the first insulating resin layer and the second insulating resin layer to fix the transparent member to the base material; and a semiconductor element provided on the other main surface side of the substrate for mounting elements and having a light-receiving or light-emitting function.

In the optical module of the above aspect, the outer edge of the transparent member may be positioned in an area between the first insulating resin layer and the second insulating resin layer on the one main surface side of the base material, and a part of the adhesive may be exposed. Also, the outer edge of the transparent member may be positioned on the first insulating resin layer on the one main surface side of the base material. Furthermore, the transparent member may be an infrared cut filter.

Appropriate combinations of each of the aforementioned constituents can also be included in the scope of the invention seeking patent protection by means of the present patent application.

### Effect of the Invention

According to the present invention, the inflow of the adhesive to the opening can be suppressed in the substrate for mounting elements, the adhesive being used for fixing the transparent member to the substrate for mounting elements.

### BRIEF DESCRIPTION OF THE DRAWINGS

FIG. 1 is a schematic cross-sectional view showing the structure of a camera module as one example of an optical module, according to a first embodiment;

FIG. 2 is a plan view showing a positional relationship among an insulating resin layer for a base material, a first insulating resin layer, and a second insulating resin layer on one main surface side of the insulating resin layer for a base material;

FIG. 3 is an enlarged cross-sectional view of principal parts, showing the first insulating resin layer and the second insulating resin layer;

FIG. 4 is a cross-sectional views of processes showing a method for forming the second insulating resin layer constituting a part of an optical module substrate according to the first embodiment, and a method for mounting a transparent member;

FIG. 5 is a cross-sectional views of the processes showing the method for forming the second insulating resin layer constituting a part of the optical module substrate according to the first embodiment, and the method for mounting the transparent member;

FIG. 6 is a cross-sectional views of the processes showing the method for forming the second insulating resin layer constituting a part of the optical module substrate according to the first embodiment, and the method for mounting the transparent member;

FIG. 7 is a cross-sectional view of principal parts showing the movement of the adhesive when bonding the transparent member;

FIG. 8 is a schematic cross-sectional view showing the structure of a camera module as one example of the optical module according to a second embodiment;

FIG. 9 is a cross-sectional view showing the structure of the conventional camera module;

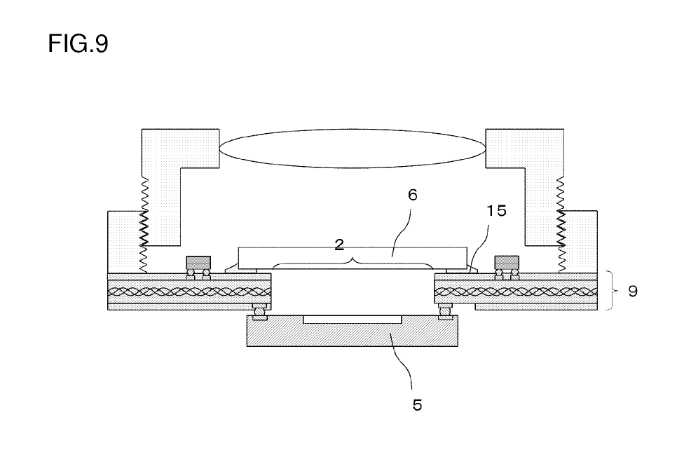

FIG. 10 is a cross-sectional views of processes showing a method for forming an insulating resin layer according to a variation; and

FIG. 11 is a cross-sectional views of the processes showing the method for forming the insulating resin layer according to the variation.

### BEST MODE FOR CARRYING OUT THE INVENTION

Embodiments of the present invention will be described below with reference to the drawings. In all of the drawings, similar symbols are given to similar components, omitting explanation as appropriate.

### First Embodiment

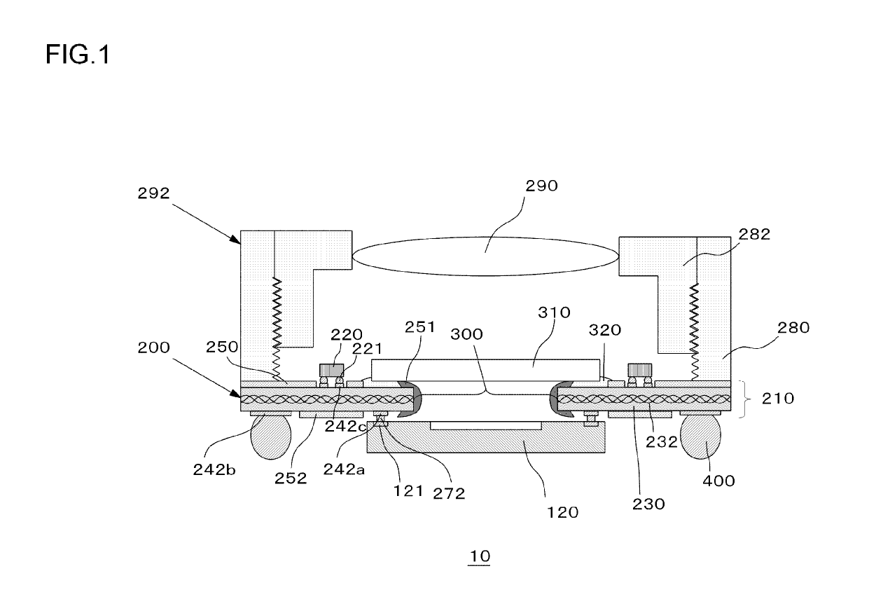

FIG. 1 is a schematic cross-sectional view showing the structure of a camera module 10 as one example of the optical module using the substrate for mounting elements, according to a first embodiment. The camera module 10 according to the present embodiment is used in an imaging apparatus such as a digital still camera, a digital video camera, and a camera built in a mobile phone.

The camera module 10 according to the first embodiment includes a circuit module 200 and a lens module 292.

The circuit module 200 has a structure in which chip components 220 are mounted on one surface of an optical module substrate (the substrate for mounting elements) 210, and a semiconductor element 120 is mounted on the other surface of the optical module substrate 210. The chip components 220 are electronic components, such as a driver IC, a power supply IC, or passive components including a resistance or a capacitance, for driving an optical lens 290 described later. The semiconductor element 120 is a light-receiving element such as a CMOS image sensor . Photodiodes are formed in a matrix on the surface of the semiconductor element 120. Each photodiode photoelectrically converts light into electric charges according to the amount of light received to output the electric charges as pixel signals.

The optical module substrate 210 includes an insulating resin layer 230 for a base material (substrate), a wiring layer (not shown), electrode parts 242 provided on parts of the wiring layer, a first insulating resin layer 250, a second insulating resin layer 251 and a third insulating resin layer 252.

The insulating resin layer 230 is used as a base material for the optical module substrate 210 and can be formed of thermosetting resin such as: a melamine derivative such as BT resin; a liquid crystal polymer; epoxy resin; PPE resin; polyimide resin; fluororesin; phenol resin; and polyamide bismaleimide. In the present embodiment, a glass cloth 232 that is one kind of an inorganic filler is embedded in the insulating resin layer 230 as a reinforcing material. The thickness of the insulating resin layer 230 is, for example, 300 μm.

Electrode parts 242 (242c) in predetermined patterns are provided on parts of one main surface of the insulating resin layer 230 exposed at an opening part of the first insulating resin layer 250 which will be described later. Although not shown, the electrode parts 242c may be provided with a plated layer such as a Ni/Au layer formed thereon. The chip components 220 are electrically connected to predetermined parts of the electrode parts 242c by solder 221. In addition, electrode parts 242 (242a, 242b) as parts of the wiring layer are provided on parts of the other main surface of the insulating resin layer 230 exposed at an opening part of the third insulating resin layer 252 which will be described later. Although not shown, the electrode parts 242 may be provided with a plated layer such as a Ni/Au layer formed thereon. Copper can be used as the material for constituting the wiring layer and the electrode parts 242a, 242b, and 242c. The electrode parts 242a and the electrode parts 242c, or the electrode part 242b and the electrode parts 242c are electrically connected through the wiring layer and a via (through hole) conductor (not shown) that penetrates through the insulating resin layer 230, at predetermined positions of the insulating resin layer 230. Further, the electrode parts 242a and the electrode part 242b are electrically connected through the wiring layer. Although not particularly shown, both of the main surfaces of the insulating resin layer 230 are provided with the wiring layers which have the same height as the electrode parts 242.

An opening 300 is provided corresponding to the installation area of the semiconductor element 120 while passing through the insulating resin layer 230 from the one main surface to the other main surface thereof. The opening 300 has a substantially “square” shape in a plan view of the insulating resin layer 230. For example, when the semiconductor element 120 mounted on the other surface side (the bottom surface side) of the insulating resin layer 230 is provided with a functional part for receiving light, the opening 300 has such a shape that the functional part for receiving light can be visually recognized in viewing the opening 300 from the one side (the top surface side) of the insulating resin layer 230. In particular, the shape of the opening 300 does not have to be in the “square” shape; it may be in a circular, elliptical, or rectangular shape, for example.

The first insulating resin layer 250 including photo solder resist or the like is provided on the one main surface of the insulating resin layer 230. The first insulating resin layer 250 is provided on a part of the one main surface of the insulating resin layer 230 on the outer side of the opening 300 so as to surround the opening 300. The first insulating resin layer 250 is not formed in a region within a predetermined distance (625 μm, for example) from the edge of the opening 300 passing through the insulating resin layer 230. The thickness of the first insulating resin layer 250 is 25 μm, for example. In addition, the first insulating resin layer 250 is provided with an opening in which the formation area of the electrode parts 242c is exposed.

The second insulating resin layer 251 continuously coats i) the upper surface of the insulating resin layer 230 in the vicinity of the edge of the opening 300, ii) the side of the opening 300 penetrating the insulating resin layer 230, and iii) the lower surface of the insulating resin layer 230 in the vicinity of the edge of the opening 300. The second insulating resin layer 251 includes photo solder resist with the light-shielding property superior to that of the first insulating resin layer 250. In the present embodiment, the second insulating resin layer 251 is formed of the resin of a black color that contains, for example, carbon black. The maximum thickness of the second insulating resin layer 251 on the one and the other main surfaces of the insulating resin layer 230 is 20 to 30 μm.

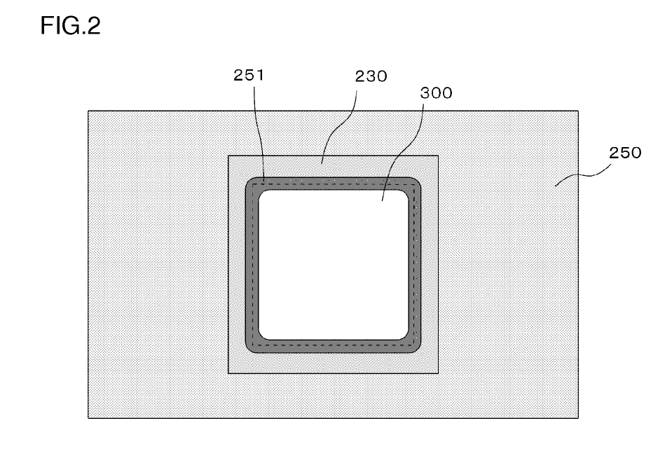

FIG. 2 is a plan view of the main surface of the insulating resin layer 230, showing the positional relationship among the insulating resin layer 230, the first insulating resin layer 250, and the second insulating resin layer 251. A dotted line shown in FIG. 2 indicates the end faces (the periphery) of the opening 300. As shown in FIG. 2, the second insulating resin layer 251 is separated from the end face of the first insulating resin layer 250 surrounding the opening 300, on the one main surface of the insulating resin layer 230.

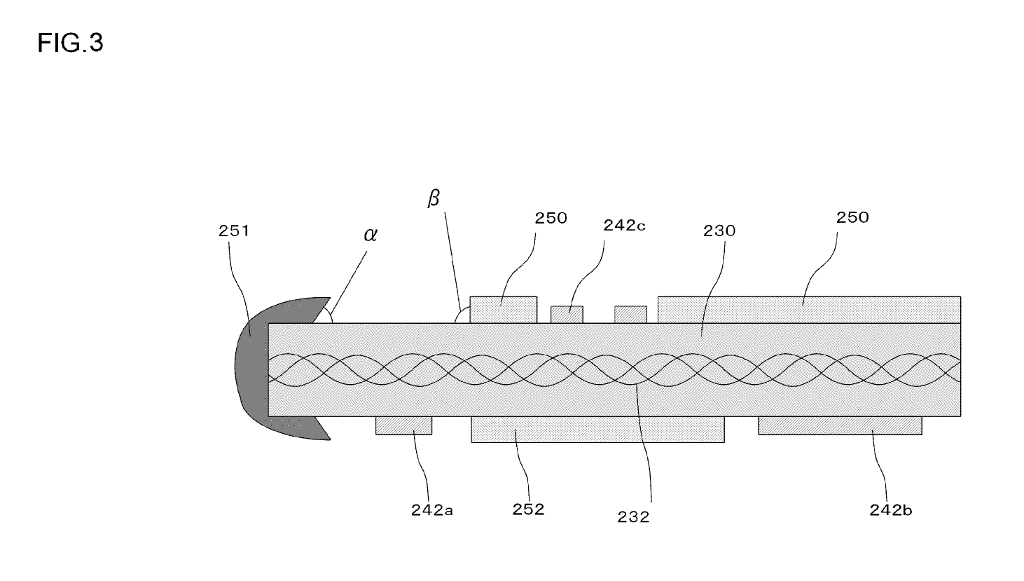

FIG. 3 is an enlarged cross-sectional view of principal parts, showing the first insulating resin layer 250 and the second insulating resin layer 251. As shown in FIG. 3, the upper end portion of the end face of the second insulating resin layer 251 in contact with the one main surface of the insulating resin layer 230 protrudes toward the first insulating resin layer 250. In more detail, an angle α, formed by the one main surface of the insulating resin layer 230, which is between the first insulating resin layer 250 and the second insulating resin layer 251, and the end face of the second insulating resin layer 251 in contact with the one main surface of the insulating resin layer 230 in the periphery of the opening 300, is smaller than an angle β formed by the one main surface of the insulating resin layer 230, which is between the first insulating resin layer 250 and the second insulating resin layer 251, and the end face of the first insulating resin layer 250 surrounding the opening 300. The angle α is 45° to 55°, and the angle β is 90°, for example.

The thickness of the second insulating resin layer 251 gradually becomes thicker as it gets farther from the opening 300 on the one main surface of the insulating resin layer 230.

On the other hand, the second insulating resin layer 251 is separated from the end face of the third insulating resin layer 252 on the side of the opening 300, on the other main surface of the insulating resin layer 230. In the present embodiment, the lower end portion of the end face of the second insulating resin layer 251 in contact with the other main surface of the insulating resin layer 230 protrudes toward the third insulating resin layer 252 described later. However, the end face of the second insulating resin layer 251 in contact with the other main surface of the insulating resin layer 230 may be perpendicular to the other main surface of the insulating resin layer 230.

Further, the third insulating resin layer 252 including photo solder resist and the like is provided on the other main surface of the insulating resin layer 230. The thickness of the third insulating resin layer 252 is 25 μm, for example. The third insulating resin layer 252 is provided with an opening for mounting stud bumps 272 on the electrode parts 242a and an opening for mounting solder 400 on the electrode part 242b. The electrode parts 242a and element electrodes 121 provided in the semiconductor element 120 are electrically connected by the stud bumps 272.

The lens module 292 including a lens barrel 280, a cylindrical body 282 and the optical lens 290 is mounted on the one main surface side (the top surface side) of the optical module substrate 210 described above. In particular, the cylindrical body 282 and the lens barrel 280 are screwed together by a screw part provided on the inner peripheral surface of the lens barrel 280. The optical lens 290 is attached to the cylindrical body 282.

A transparent member 310 is mounted on the one main surface of the insulating resin layer 230 while being superimposed on the second insulating resin layer 251 and covering the opening 300. In particular, the transparent member 310 has a shape larger than the aperture shape of the opening 300, the peripheral part of the transparent member 310 being superimposed on the insulating resin layer 230 in the vicinity of the opening 300. The second insulating resin layer 251 provided on the one main surface of the insulating resin layer is settled in the portion where the transparent member 310 and the insulating resin layer 230 are superimposed on one another, and the transparent member 310 is supported by the portion where the second insulating resin layer 251 has the maximum thickness. In addition, an adhesive 320 is filled in the portion separating the second insulating resin layer 251 from the first insulating resin layer 250 on the one main surface of the insulating resin layer 230, the adhesive 320 bonding the insulating resin layer 230, the second insulating resin layer 251, and the transparent member 310. In other words, the outer edge of the transparent member 310 is positioned in an area between the first insulating resin layer 250 and the second insulating resin layer 251, with a part of the adhesive 320 exposed. The thickness of the transparent member 310 is 300 v, for example. The transparent member 310 may also be supported by the adhesive 320.

The transparent member 310 is formed of the material capable of transmitting electromagnetic waves of a specific wavelength range. Specifically, the transparent member 310 is an IR cut filter. By having the IR cut filter as the transparent member 310, excessive infrared rays of longer wavelengths entering the semiconductor element 120 are intercepted. In addition to the IR cut filter, an ultraviolet cut filter, a color filter, a polarizing plate, a combustion gas transmission filter, a flame temperature measurement filter, a plastic temperature measurement filter, a quartz glass transmission filter, a glass temperature measurement filter, and the like can be used as the transparent member 310.

A coefficient of thermal expansion of the transparent member 310 is equal to a coefficient of thermal expansion of the inorganic filler embedded in the insulating resin layer 230, namely, the glass cloth 232 in the present embodiment. The coefficient of thermal expansion (° C.⁻¹) of glass cloth used in general is 5.5×10⁻⁶. In this case, it is preferred that the coefficient of thermal expansion (° C.⁻¹) of the transparent member 310 be 5.5×10⁻⁶. The coefficients of thermal expansion (° C.⁻¹) of quartz glass, borosilicate glass, and soda quartz glass are 5.6×10⁻⁷, 5.2×10⁻⁶, and 8.5×10⁻⁶, respectively. Depending on the material constituting the glass cloth, the coefficient of thermal expansion (° C.⁻¹) of the transparent member 310 can fall within the range of 5×10⁻⁷ to 9×10⁻⁶. The coefficient of thermal expansion (° C.⁻¹) of the epoxy resin is approximately 6×10⁻⁵, which is outside the range of the coefficient of thermal expansion of the transparent member 310.

(Method for Forming the Second Insulating Resin Layer and the Method for Mounting the Transparent Member)

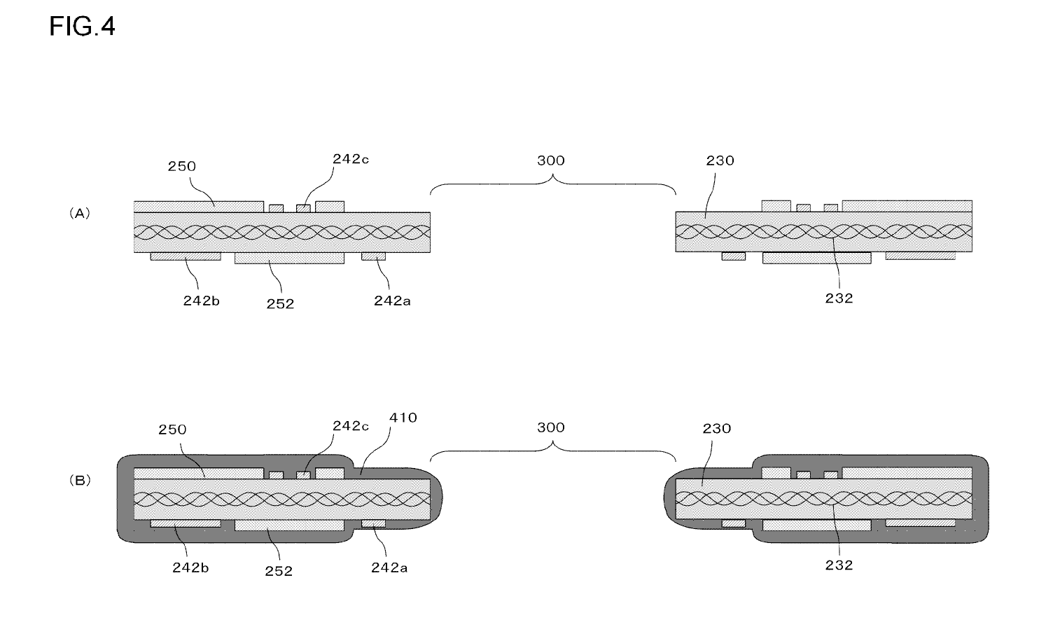

FIGS. 4 to 6 are cross-sectional views of processes showing the method for forming the second insulating resin layer constituting a part of the optical module substrate according to the first embodiment, and the method for mounting the transparent member.

First, the insulating resin layer 230 is prepared, wherein the opening 300 is provided, the electrode parts 242 being a part of the wiring layer and the first insulating resin layer 250 are patterned on the one main surface, and the third insulating resin layer 252 is patterned on the other main surface, as shown in FIG. 4(A). The first insulating resin layer 250 and the third insulating resin layer 252 are obtained by patterning to form predetermined openings by using a photomask (not shown), after attaching the film-shaped photo solder resist to the insulating resin layer 230. Here, the first insulating resin layer 250 may form a ring shape around the opening 300, or a ring shape with a portion thereof chipped.

Now, as shown in FIG. 4(B), the insulating resin layer 230 is coated with liquid resin 410 from top and bottom surfaces thereof by means of a spray nozzle method, a roll coater method, or the like. In particular, nozzles (not shown) from which the liquid resin 410 is ejected are arranged on the top and bottom surface sides of the insulating resin layer 230. By moving the insulating resin layer 230(by moving the substrate 210) in one direction while turning the nozzles from left to right in the shape of a fan, the resin 410 is coated to cover the entire surface of the insulating resin layer 230, the first insulating resin layer 250, the electrode parts 242a, 242b, and 242c, and the third insulating resin layer 252. Then, a solvent in the resin 410 is evaporated by heating. This resin 410 includes photosensitive epoxy resin (PSR: Photo Solder Resist), into which powder such as carbon black is mixed to turn black.

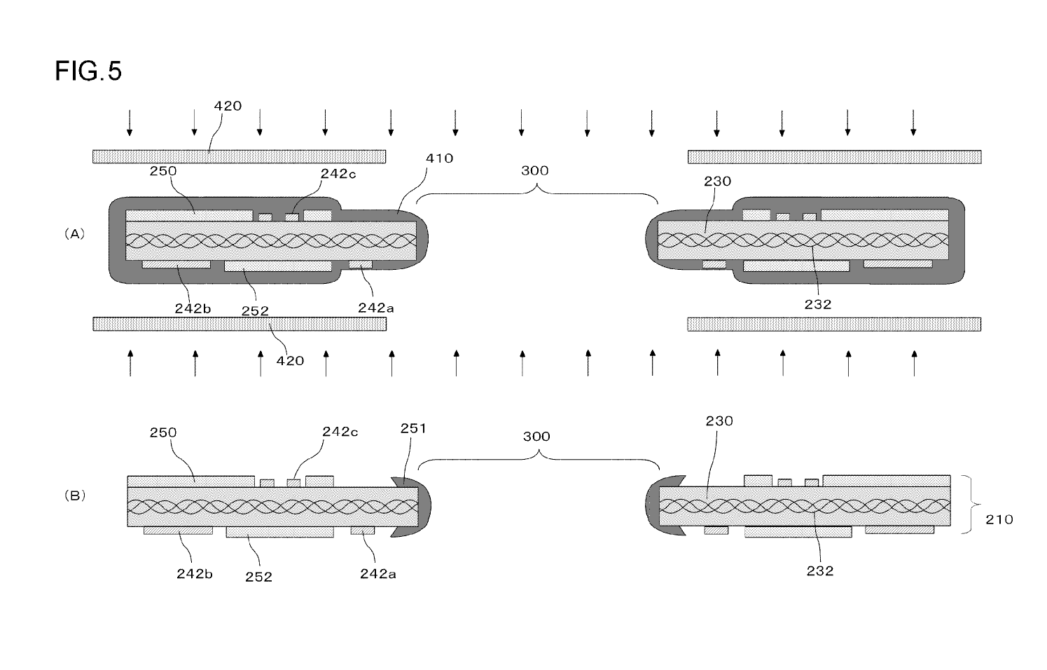

Next, as shown in FIG. 5(A), the insulating resin layer 230 is exposed from the top and bottom surface sides thereof, after arranging a mask 420 having a pattern to expose the resin 410 in the vicinity of the opening 300.

As shown in FIG. 5(B), the resist is developed after removing the photomask 420. The resin 410 outside the vicinity of the opening 300 is removed, thereby forming the second insulating resin layer 251 that continuously coats i) the upper surface of the insulating resin layer 230 in the vicinity of the edge of the opening 300, ii) the side of the opening 300, and iii) the lower surface of the insulating resin layer 230 in the vicinity of the edge of the opening 300. Since the resin 410 has high light-shielding property, the edge that defines the portion affected by exposure is progressively nearer the opening 300 toward the insulating resin layer 230. Consequently, there is obtained the structure where the upper end portion of the end face of the second insulating resin layer 251 in contact with the one main surface of the insulating resin layer 230 protrudes toward the first insulating resin layer 250. The optical module substrate 210 is thus obtained by the processes above.

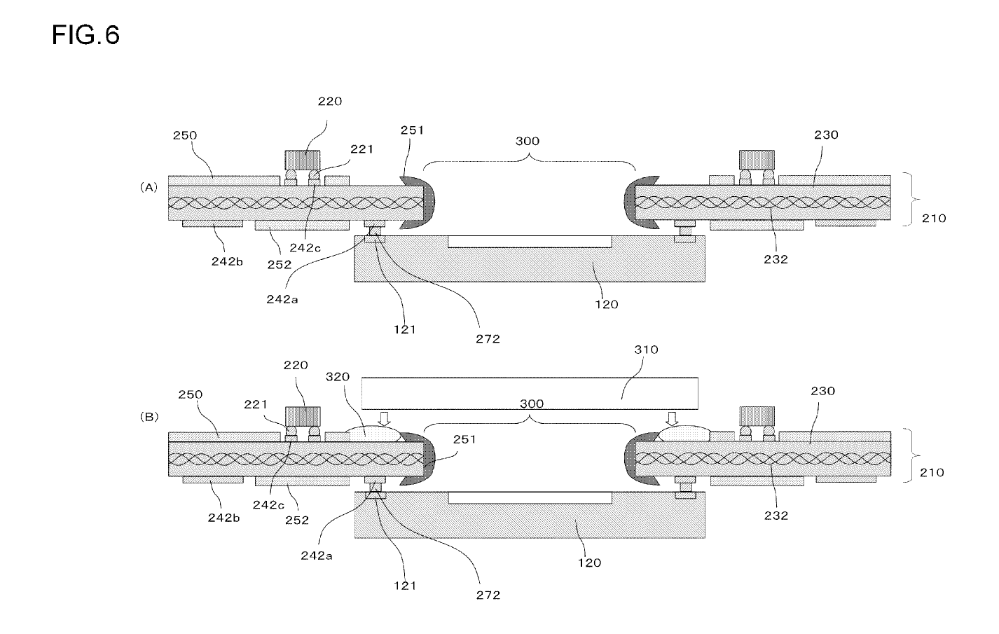

Now, as shown in FIG. 6(A), the element electrodes 121 of the semiconductor element 120 and the electrode parts 242a are electrically connected via the stud bumps 272, and the semiconductor element 120 is mounted on the other surface side (the bottom surface side) of the optical module substrate 210. The semiconductor element 120 can be mounted with the one surface of the optical module substrate 210 turned to a base (not shown), i.e., with the optical module substrate 210 turned upside down. In this case, the surface of the first insulating resin layer 250 to be brought into contact with the base can be made flat by using film-shaped=insulating resin for the first insulating resin layer 250. This allows for the stability of the optical module substrate 210 to be improved when it is loaded on the base. As a result, the operability in mounting the semiconductor element 120 and the mounting accuracy of the semiconductor element 120 can be improved. The solder 221 is used to electrically connect the chip components 220 and the electrode parts 242c, and the chip components 220 are mounted on the one surface side (the top surface side) of the optical module substrate 210.

Next, as shown in FIG. 6(B), the adhesive 320 is injected on the one main surface of the insulating resin layer for a base material 230 corresponding to the gap between the first insulating resin layer 250 and the second insulating resin layer 251. The transparent member 310 is then pressed down from the top to cover the opening 300, thereby fixing the transparent member 310.

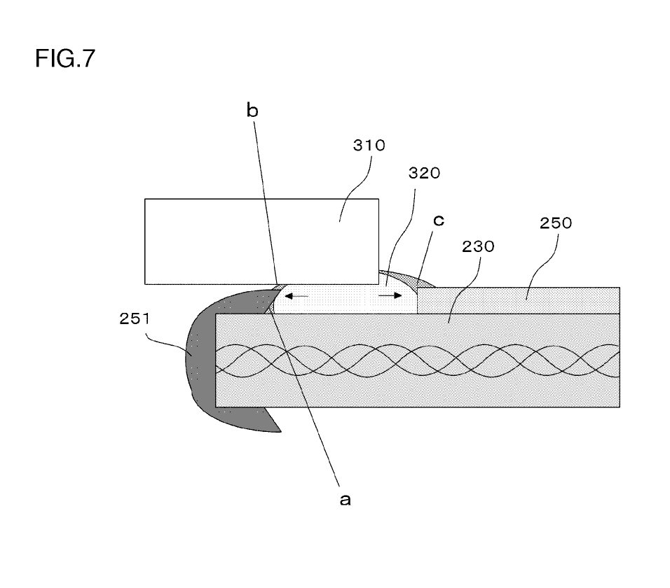

FIG. 7 is a cross-sectional view of principal parts showing the movement of the adhesive 320 when bonding the transparent member 310. As shown in FIG. 7, when the transparent member 310 is pressed down from the top, the volume of the adhesive 320 pushed out by the transparent member 310 flows toward inner and outer sides of the insulating resin layer 230. More specifically, the adhesive 320 flows into a gap a between the tapered portion of the second insulating resin layer 251 and the insulating resin layer 230, and into a gap b between the second insulating resin layer 251 and the transparent member 310, toward the inner side of the insulating resin layer 230. Further, the adhesive 320 flows into a region c formed between the first insulating resin layer 250 and the transparent member 310 toward the outer side of the insulating resin layer 230. Herein, the relation of S=Sa+Sb+Sc and Sa+Sb=Sc is established, where S denotes the volume pushed out by the transparent member 310, and Sa, Sb, and Sc denote the volume of the gaps a, b and the region c, respectively.

In the optical module substrate 210 of the present embodiment, the amount of the adhesive 320 flowing into the gap decreases in proportion to the volume of the adhesive 320 flowing into the gap b toward the inner side of the insulating resin layer 230, since the end face of the second insulating resin layer 251 is tapered.

According to the camera module 10 described above, at least the following effects can be acquired.

(1) With the structure where the upper end portion of the end face of the second insulating resin layer 251 in contact with the one main surface of the insulating resin layer 230 protrudes toward the first insulating resin layer 250, the adhesive 320 pushed out can flow into the gap between the end face of the second insulating resin layer 251 and the one main surface of the insulating resin layer 230, by pressing down the transparent member 310. The more adhesive 320 flows into the gap, the less adhesive 320 used for fixing the transparent member 310 passes between the second insulating resin layer 251 and the transparent member 310 to flow toward the opening 300. Consequently, the aperture shape of the opening 300 can be maintained as designed, thereby suppressing the decrease in the light-receiving efficiency of the semiconductor element 120.

(2) With the structure where the upper end portion of the end face of the second insulating resin layer 251 in contact with the one main surface of the insulating resin layer for a base material 230 protrudes toward the first insulating resin layer 250, the gap into which the adhesive 320 flows is formed between the end face of the second insulating resin layer 251 and the one main surface of the insulating resin layer 230. The adhesive 320 flowing into the gap adds the anchor effect to the adhesion of the transparent member 310 by the adhesive 320, thereby possibly improving the adhesion strength of the transparent member 310.

(3) The light-shielding property of the second insulating resin layer 251 superior to that of the first insulating resin layer 250 causes light received by the semiconductor element 120 to be reflected less in the second insulating resin layer 251. As a result, the diffused reflection of light incident on the semiconductor element 120 with an oblique angle can be suppressed.

### Second Embodiment

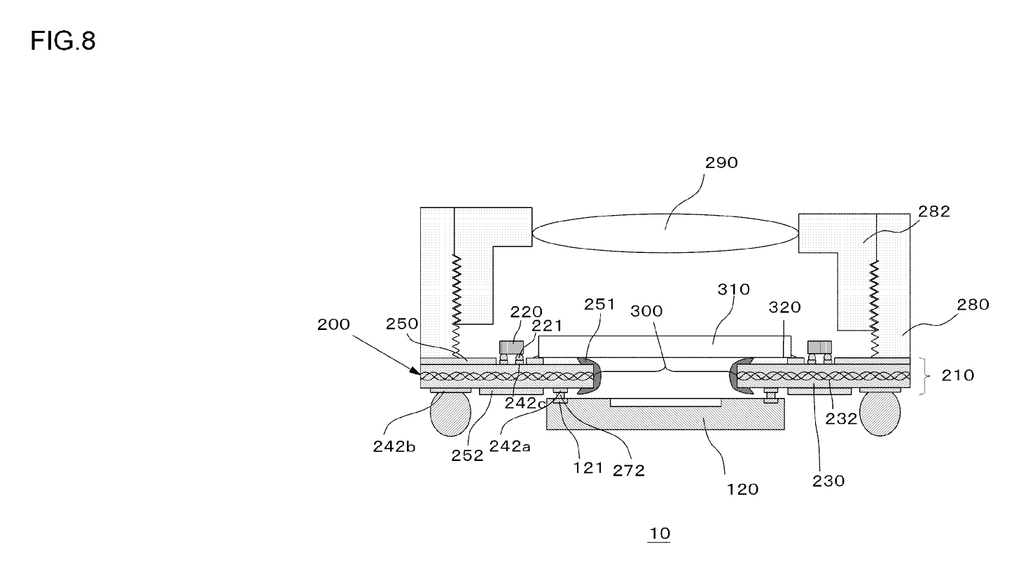

FIG. 8 is a schematic cross-sectional view showing the structure of a camera module 10 as one example of the optical module using the substrate for mounting elements, according to a second embodiment. The fundamental structure of the camera module 10 according to the present embodiment is similar to that of the first embodiment. Explanation will be omitted as appropriate for the structure of the camera module 10 according to the second embodiment, in the case where the structure is similar to that of the first embodiment.

In the camera module 10 according to the present embodiment, the outer edge of the transparent member 310 is positioned extending on top of the first insulating resin layer 250 on the one main surface side of the insulating resin layer 230. In other words, the one main surface of the insulating resin layer 230 of the region between the first insulating resin layer 250 and the second insulating resin layer 251 is covered by the transparent member 310, and the adhesive 320 is filled in a space surrounded by the first insulating resin layer 250, the second insulating resin layer 251, the one main surface of the insulating resin layer 230, and the transparent member 310.

According to the camera module 10 of the present embodiment, the following effect can be acquired in addition to the effects acquired by the camera module in the first embodiment.

(4) The adhesion strength of the transparent member 310 by the adhesive 320 can be further improved since the contact area between the adhesive 320 and the transparent member 310 is increased.

The present invention is not limited to each of the aforementioned embodiments. Variations such as various design changes can be added based on the knowledge of those skilled in the art, and embodiments to which such variations are added can also be included in the scope of the present invention.

In the aforementioned embodiments, for example, the semiconductor element 120 is connected via the stud bumps to the other main surface (the bottom surface) of the insulating resin layer 230 by a flip chip method. However, the semiconductor element 120 may also be connected by the flip chip method via solder balls.

Furthermore, the semiconductor element 120 is a light-receiving element in each of the aforementioned embodiments; however, it may also be a light-emitting element having a light-emitting function such as an LED.

(Variation of the Method for Forming the Insulating Resin Layer)

In each of the aforementioned embodiments, the first insulating resin layer 250 and the third insulating resin layer 252 are formed by patterning the film-shaped photo solder resist. In this variation, however, the first insulating resin layer 250 and the third insulating resin layer 252 are formed by using liquid photo solder resist.

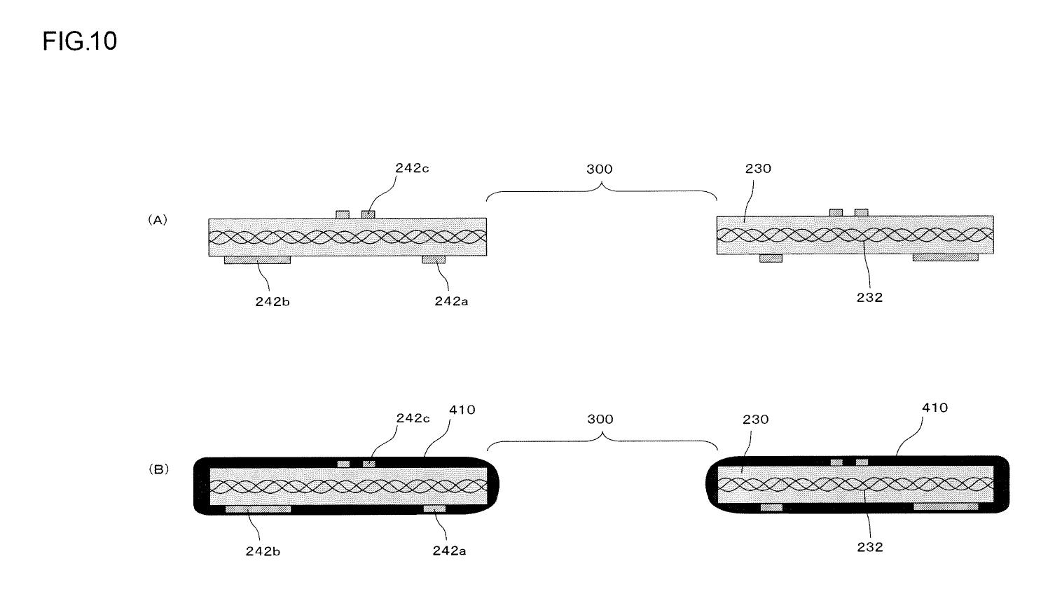

First, the insulating resin layer 230 is prepared, wherein the opening 300 is provided and the electrode parts 242 being a part of the wiring layer are patterned on the main surfaces, as shown in FIG. 10(A).

Then, as shown in FIG. 10(B), the insulating resin layer 230 is coated with the liquid resin 410 from the top and bottom surfaces thereof by means of the spray nozzle method, the roll coater method, or the like. In particular, the nozzles (not shown) from which the liquid resin 410 is ejected are arranged on the top and bottom surface sides of the insulating resin layer 230. By moving the insulating resin layer 230 in one direction while turning the nozzles left and right in the shape of a fan, the resin 410 is coated to cover the entire surface of the insulating resin layer 230 and the electrode parts 242a, 242b, and 242c . Then, the solvent in the resin 410 is evaporated by heating. This resin 410 includes photosensitive epoxy resin (PSR: Photo Solder Resist), into which the powder such as carbon black is mixed to turn black.

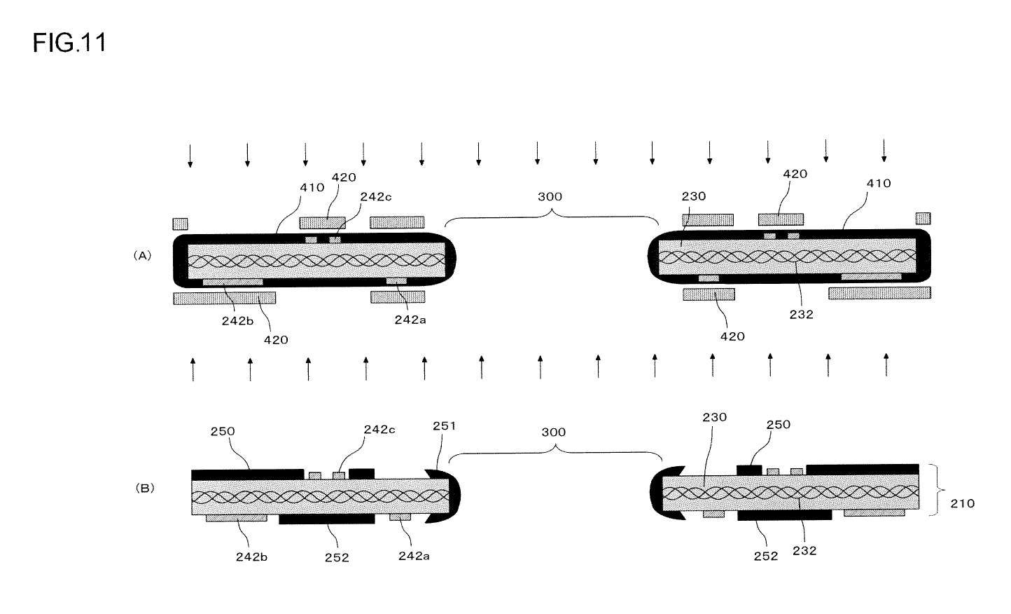

Next, as shown in FIG. 11(A), the insulating resin layer 230 is exposed from the top and bottom surface sides thereof, after arranging the mask 420 having the pattern to expose the resin 410 in the vicinity of the opening 300 and the area in which the first insulating resin layer is formed.

As shown in FIG. 11 (B), the resist is developed after removing the photomask 420. As a result, the resin 410 outside the vicinity of the opening 300 and outside the area where the first insulating resin layer 250 and the third insulating resin layer 252 are formed is removed, thereby forming the second insulating resin layer 251, the first insulating resin layer 250, and the third insulating resin layer 252, the second insulating resin layer 251 continuously coating i) the upper surface of the insulating resin layer 230 in the vicinity of the edge of the opening 300, ii) the side of the opening 300, and iii) the lower surface of the insulating resin layer 230 in the vicinity of the edge of the opening 300. The insulating resin layer is thinner in the vicinity of the opening; as a result, the end face of the second insulating resin layer 251 becomes evidently overexposed, forming a smaller angle with the substrate. Consequently, there is obtained the structure where the upper end portion of the end face of the second insulating resin layer 251 in contact with the one main surface of the insulating resin layer 230 protrudes toward the first insulating resin layer 250. The optical module substrate 210 is thus obtained by the processes above.

According to the method for forming the first insulating resin layer 250 and the third insulating resin layer 252 of the variation, the first insulating resin layer 250, the second insulating resin layer 251, and the third insulating resin layer 252 can be formed all at once from the same material by the same processes. Thus, the number of processes required for manufacturing the optical module substrate can be decreased, and the cost of manufacturing the optical module substrate can eventually be reduced.

Moreover, the liquid resist has excellent followability to uneven surfaces, which allows for the positions of recognition marks (through-holes) to be recognized based on the shape of the first insulating resin layer 250, even when relatively small recognition marks are formed in the insulating resin layer 230. Therefore, the first insulating resin layer 250 does not need to be formed of a transparent material, so that the resist of a dark color such as black can be used for the first insulating resin layer 250. As a result, the diffused reflection within the camera module 10 can be suppressed.

### DESCRIPTION OF THE REFERENCE NUMERALS

10 camera module, 120 semiconductor element, 200 circuit module, 210 optical module substrate, 220 chip component, 230 insulating resin layer for a base material, 250 first insulating resin layer, 251 second insulating resin layer, 251 second insulating resin layer, 252 third insulating resin layer, 292 lens module, 272 stud bump, 280 lens barrel, 282 cylindrical body, 290 optical lens, 310 transparent member, 320 adhesive

### INDUSTRIAL APPLICABILITY

The present invention can be applied to a substrate for mounting elements used in an optical module such as a camera module, and to the optical module using the substrate It should be noted that the invention according to the present embodiment may be specified according to the items described below.

1. A substrate for mounting elements, comprising:
a base material provided with an opening passing therethrough from one main surface to the other main surface;
a first insulating resin layer provided at a part of the one main surface of the base material on the outer side of the opening so as to surround the opening; and
a second insulating resin layer coating an edge portion of the opening and an end face of the opening continuously on the one main surface of the base material, the edge portion of the opening being separated from an end face of the first insulating resin layer surrounding the opening, wherein
an upper end portion of an end face of the second insulating resin layer in contact with the one main surface of the base material protrudes toward the first insulating resin layer.

2. The substrate for mounting elements according to claim 1, wherein
an angle formed by the one main surface of the base material, which is between the first insulating resin layer and the second insulating resin layer, and the end face of the second insulating resin layer in contact with the edge portion of the opening is smaller than an angle formed by the one main surface of the base material, which is between the first insulating resin layer and the second insulating resin layer, and the end face of the first insulating resin layer surrounding the opening.

3. The substrate for mounting elements according to claim 1 or 2, wherein
a light-shielding property of the second insulating resin layer is superior to a light-shielding property of the first insulating resin layer.

4. The substrate for mounting elements according to claim 3, wherein
the second insulating resin layer contains insulating resin and black powder.

5. An optical module comprising:
the substrate for mounting elements according to either of claims 1 to 4;
an optical lens provided on the one main surface side of the substrate for mounting elements;
a transparent member disposed on the one main surface side of the substrate for mounting elements to be superimposed on the second insulating resin layer and cover the opening;
an adhesive provided on the one main surface of the base material between the first insulating resin layer and the second insulating resin layer to fix the transparent member to the base material; and
a semiconductor element provided on the other main surface side of the substrate for mounting elements and having a light-receiving or light-emitting function.

6. The optical module according to claim 5, wherein
an outer edge of the transparent member is positioned in an area between the first insulating resin layer and the second insulating resin layer on the one main surface side of the base material, with a part of the adhesive exposed.

7. The optical module according to claim 5, wherein
the outer edge of the transparent member is positioned on top of the first insulating resin layer on the one main surface side of the base material.

8. The optical module according to either of claims 5 to 7, wherein
the transparent member is an infrared cut filter.
